(19) United States
(12) Patent Application Publication
(10) Pub. No.: US 2011/0256378 A1
(43) Pub. Date: Oct. 20, 2011

(54) CROSS LINKING MEMBRANE SURFACES

(75) Inventors: Christopher H. Collins, Melrose, MA (US); Imtiaz J. Rangwalla, Andover, MA (US)

(73) Assignee: Energy Sciences, Inc.

(21) Appl. No.: 13/086,230

(22) Filed: Apr. 13, 2011

Related U.S. Application Data
(60) Provisional application No. 61/323,610, filed on Apr. 13, 2010.
(60) Provisional application No. 61/323,605, filed on Apr. 13, 2010.
(60) Provisional application No. 61/323,618, filed on Apr. 13, 2010.

(51) Int. Cl. B32B 27/32; C08F 36/04; H01J 37/30

(52) U.S. Cl. 428/220; 264/485; 526/335

(57) ABSTRACT

The present invention relates, in part, to high energy processes for manufacturing cross-linked polyolefins. The polyolefins described herein are capable of undergoing further processing without compromising their physical properties and dynamic performance.

This application claims the benefit of U.S. Provisional Application Nos. 61/323,610, 61/323,605, and 61/323,618, filed Apr. 13, 2010, each of which are incorporated by reference herein in their entirety.

The present disclosure relates to high energy processes for manufacturing cross-linked polyolefins. The polyolefins are capable of undergoing further processing without compromising their physical properties and dynamic performance of the cross-linked product.

Cross-linking (vulcanization) of elastomeric materials involves connection of loosely held molecular chains into a three-dimensional network of polymeric chains capable of supporting a sustained load (stress) and/or withstanding a constant deformation (strain). Enhanced physical properties of a cross-linked elastomer can include, for example, high tensile strength, low compression set, recoverable elongation, high tear energy, and increased dynamic performance. Each property can be influenced by the degree or extent of cross-linking. It is well known, for example, that increasing the amount of cross-linking enhances the physical and dynamic performance of elastomers. See, e.g., Handbook of Engineering Polymeric Materials, Nicholas P. Cheremisinoff, ISBN #0-8247-9799-X, 1997; and Cray Valley Resins par excellence, “Telechelic Poly(butadiene) Diacrylate for the Radical Cure of Elastomers,” Steven K. Henning and Jeffrey Klang, Cray Valley USA, LLC, January 2010.

High-temperature peroxide based cure processes have been used to cross-link elastomers or polymeric membranes. Peroxide cures produce oxygen-centered radicals which form the basis for allowing the elastomers or polymeric membranes to cross-link. This process requires high temperature to initiate the radical process, is not selective, and the resulting end product primarily consists of materials that contain fully cross-linked polymers. Moreover, it is well established that completely cross-linked materials have improved properties such as physical and dynamic performance, and can be used to produce commercially superior products.

Despite the benefits of materials having both good physical and dynamic performance, the oxygen-centered radicals formed by the peroxide cure process further combine to form highly reactive oxygen-centered radical intermediates that subsequently undergo side reactions to form unwanted byproducts. However, reducing these byproducts is extremely difficult because of the high temperatures and long treatment times required to achieve sufficient cross-linking of the materials.

Other drawbacks to peroxide based cure methods include increased costs associated with the production of materials, longer cure times, low radical flux, over expulsion of waste generated during the heating process, and overall inefficiency leading to increased emissions and carbon footprinting. In addition, because the peroxide cure process is not selective and results in fully cross-linked polymers, further processing of the polymers is compromised.

For example, in the roofing industry, it is important to interfacially melt blend the surface ply and the base membrane of the roofing materials. This interfacial melt produces a seamless bond between the cross-linkable region of the surface ply and the base membrane, which in turn results in a more durable material that is easier to attach to the surface of the roof. In contrast, peroxide based cures produce materials that are fully cross-linked polymers, and would require extensive heat and time to effectively melt blend the surface ply and the base membrane of the roofing materials together.

Thus, there is a present need to develop better ways to reduce the costs, time, and waste associated with the industrial processing of cross-linked materials used, for example, in tire and roofing products and processes.

Radiation curing such as electron beam (EB) processing is known to be a suitable alternative to high-temperature peroxide curing methods. In EB processing energetic electrons are used instead of heat. Initiation of cross-linking proceeds through carbon-centered radicals, which, unlike oxygen-centered radials in the peroxide cure, do not readily react to form unwanted intermediates or byproducts. EB processing also allows for greater versatility controlling the amount of cross-linking by varying certain parameters such as, for example, voltage, current, power, etc.

Other advantages of using EB processing over other methods include: decreased costs associated with the cross-linking of materials; low temperature processing, e.g., performed at ambient temperature; low energy consumption; instantaneous cure times; precise control of cross-linking action to a predetermined depth in the treated material; and easy adaptability to in-line web-based processing. Efficient particle beam processors of this nature are discussed in, for example, U.S. Pat. Nos. 6,426,507; 6,610,376; 7,026,635; and 7,348,580.

In EB processing, the energetic electrons can be used to modify the molecular structure of a wide variety of products and materials. For example, electrons can be used to alter specially designed liquid coatings, inks, rubbers, and adhesives. Liquid coatings treated with EB processing may include printing inks, varnishes, silicone release coatings, primer coatings, pressure sensitive adhesives, barrier layers and laminating adhesives. EB processing may also be used to alter and enhance the physical characteristics of solid materials such as paper, substrates and non-woven textile substrates, and polymeric materials, such as elastomers, all specially designed to react to EB treatment.

EB processing devices having increased efficiency both at lower (such as 110 kVolts or less) and higher (such as 110 kVolts or greater) voltages, have been developed and are useful for producing commercially viable products, including for example, various food packaging materials, e.g., ethylene based sealant films, liquid coatings, inks, and adhesives. See, e.g., U.S. Pat. Nos. 6,426,507; 6,610,376; 7,026,635; and 7,348,580.

Despite the advantages of utilizing EB devices, and the knowledge that increased cross-linking enhances the physical and dynamic performance of materials, the problem remains of how to manufacture a commercially viable product that has sufficient physical and dynamic properties and that is also easy to further process based on industrial need.

Surprisingly, the inventors found that partial curing of materials using EB processing results in materials with physical and dynamic properties similar to those obtained using conventional peroxide based methods and previous EB processing procedures, but having improved versatility. In one embodiment, the method described herein allows for further processing of the partially cross-linked material without the need for harsh and/or labor intensive conditions, and results in commercially viable products having all the beneficial properties associated with EB and/or peroxide cure methods that result in completely cross-linked materials.

In one embodiment, the present invention relates to methods of generating partially cured multi-layered materials using particle beam processing. In one embodiment, the particles only penetrate a portion of a multi-layered material. The depth of penetration, e.g., to about 50% of the total thickness, will depend on the end use. The amount of cross-linking will also depend on the end use. For example, an average cross-linked density of about 35% may produce a material having a temperature resistance of approximately 250° F., whereas a cross-linked density of about 50% may produce a material having a higher temperature resistance.

Particle beam processing may occur over the full surface of the membrane, e.g., a single surface cross-linked membrane whereby the particles penetrate to a depth of about 50% of the total thickness across the entire surface, but the other surface(s) is left untreated.

It is also understood that the degree of cross-linking is dependent on the depth of penetration. In one embodiment, the depth of penetration can be altered to achieve a certain cross-link density.

Alternatively, particle beam processing may occur only at predetermined portions of the membrane, such as along the edges, a center portion, or such that the perimeter edges are left untreated (i.e., non cross-linked).

For example, a specific end use may require that one portion of the material being treated should receive EB particle treatment up to a penetration depth “X”, while another portion receives EB particle treatment up to a penetration depth “Y”, each of “X” and “Y” representing the same or different depths of particle penetration. Thus, different portions or sections of the treated material may have different degrees of cross-linking and hence different properties.

In another embodiment, the material that is EB treated could receive radiant dosages along a gradient so that as you traverse the width and/or length of the material there is an increasing depth of penetration and hence degree of cross-linking.

In one embodiment, the present invention also relates, in part, to materials made by the process described herein. In another embodiment, the resulting materials exhibit substantially similar, the same, or better properties when compared to polymer materials having an average cross-linked density of greater than about 40%.

### BRIEF DESCRIPTION OF THE FIGURES

FIG. 1 is a schematic view of the particle beam processing device according to one embodiment of the present invention;

FIG. 2 is a schematic view of a voltage profile of an electron beam;

FIG. 3 is a front view of the particle beam processing device according to an embodiment of the present invention;

FIG. 4 is a chart of depth dose profiles as a function of thickness of a 12.5 micron titanium foil measured at operating voltages ranging from 125 to 300 kVolts;

FIG. 5 is a schematic representation of a full width cross-linked membrane, where the membrane is cross-linked to a partial depth of about 50% penetration;

FIG. 6 is a schematic representation of seeming the non cross-linked bottom layer of the membrane in FIG. 5, by abutting in a “serged” style system;

FIG. 7 is a schematic representation of seeming the non cross-linked bottom layer of the membrane in FIG. 5, by overlapping adjacent membranes; and

FIG. 8 is a schematic view of cross-linking the center of the membrane while leaving a portion of the edges noncross-linked.

A particle beam processing device comprises a power supply, a particle generating assembly, a foil support assembly, and a processing assembly.

The term “partial penetration” as defined herein means up to about 50% of the total thickness of a material is penetrated or treated with particles generated from a particle beam processing device.

The term “partial curing” means a material is partially cured such that an overall average cross-linked density is achieved. The overall average cross-linked density desired is partially dependent on the required end use and properties of the material. For example, in the roofing industry heat resistance may be of greater importance than tensile strength and thus an overall average cross-linked density of about >40% may be desirable. To the contrary, in the packaging industry and average cross-linked density of about >30% may be desirable. Thus, “partial curing” is intended to cover average cross-linked density ranges from about 20% to about 100%, including from about 30% to about 80%, from about 35% to about 60%, and about >40%.

The term “about” or “approximately” as used herein means within an acceptable error range for the particular value as determined by one of ordinary skill in the art, which will depend in part on how the value is measured or determined, e.g., the limitations of the measurements system. For example, “about” can mean within one or more than one standard deviation per the practice in the art. Alternatively, “about” can mean a range of up to 20%, such as up to 10%, up to 5%, and up to 1% of a given value.

The term “portion” is intended to mean any portion of the material. By way of example only, the portion can include the entire top surface of the material, the entire bottom surface of the material, a center portion of the top or bottom surface of the material, or any portion of the edges of the material.

The term “single surface” is intended to mean a single side of the material. For example, a single side may be the entire top surface or entire bottom surface of the material, but not both. It would be understood that a “single surface” as referred to herein, means the surface that is being treated with particle beam processing.

As used herein, substantially the same properties refers to a polymer material having at least two comparable or similar mechanical, physical, and/or chemical properties, such as tensile strength, compression, tear energy, load, elasticity, transport properties, morphologies, melting point, glass transition temperature, mixing behavior, bonding properties, degradation, chemical resistance, temperature resistance, and the like.

Dose is the energy absorbed per unit mass and is measured in terms of megarads (Mrad), which is equivalent to 2.4 calories per gram. A higher number of electrons absorbed reflects a higher dose value. In application, dose is commonly determined by the material of the coating and the depth of the substrate to be cured. For example, a dose of 5 Mrad may be required to cure a coating on a substrate that is made of rice paper and having a mass density of 20 gram/m². Alternatively, a dose of 7 or 10 Mrad may be required to cure a substrate that is made of rubber or roofing material having mass densities of about 1000 gram/m² and 2000 gram/m², respectively. Dose is directly proportional to the operating beam current which is the number of electrons extracted, and inversely proportional to the feed speed of the substrate, as expressed by the following formula:

Dose=K·(I/S)

whereby I is the current measured in mAmp, S is the feed speed of the substrate measured in feet/min, and K is a proportionality constant which represents a machine yield of the processing device, or the output efficiency of that particular processing device.

A particle beam processing device that has higher efficiency for causing a chemical reaction on a substrate is described herein. The device comprises a power supply, a vacuum pump to create and maintain a vacuum environment in a vessel, and a particle generating assembly located in a vacuum vessel and connected to the power supply operating at a first voltage in a range of 150 kVolts or more. The particle generating assembly includes at least one filament for generating a plurality of particles upon heating. The device also comprises a foil support assembly and a processing assembly. The foil support assembly operates at a second voltage, which is higher than the first voltage, to permit at least a portion of the particles to travel from the first to the second voltage and exit the foil support assembly. The foil support assembly may comprise a thin foil made of titanium or alloys thereof having a thickness of about 12 micrometers. The processing assembly receives the particles exiting the foil support assembly for use to cause the chemical reaction. A machine yield (K) of the processing device is determined according to:

$$K = \frac{Dose \cdot Speed}{Current}$$

whereby:

K is machine yield measured in Mrads·feet/min/mAmp,

Dose is energy absorbed per unit mass measured in Mrads,

Speed is feed rate of the substrate measured in feet/min, and

Current is the number of electrons extracted from the heated filament measured in mAmp.

In one embodiment, the present invention relates to a method for selectively cross-linking a polymer material using a particle beam device, comprising,

selectively treating a portion of a polymer material with a particle beam for a sufficient period of time to produce a cross-linked portion, wherein

said treatment results in the polymer material having an average cross-linked density of about 20% to about 100%, and wherein the polymer material has substantially the same properties as a polymer material having the same chemical composition and a higher cross-linked density.

In one embodiment, the present invention relates to a method for selectively cross-linking a polymer material using a particle beam device, comprising:

providing a particle beam generating assembly including at least one filament;

applying an operating voltage greater than or equal to about 150 kV to the filament to create a plurality of particles;

causing the plurality of particles to pass through a thin foil having a thickness of about 12.5 microns; and

treating a portion of the material with the plurality of particles at a dosage of about 3 Mrads to 12 Mrads, wherein said treatment results in the polymer material having an average cross-linked density of about 20% to about 100%, and wherein the polymer material has substantially the same properties as a polymer material having the same chemical composition and a higher cross-linked density.

In one embodiment, the plurality of particles penetrates said portion at a depth of about 50% of the total thickness.

In one embodiment, the portion comprises a single surface, two single surfaces, or a center portion of the single surfaces, or combinations thereof.

In one embodiment, the edges of the polymer material are left untreated, i.e., not penetrated with the plurality of particles.

In one embodiment, the operating voltage ranges from about 150 kV to about 300 kV.

In one embodiment, the thin foil is a titanium foil.

In one embodiment the total thickness of the polymer material ranges from about 100 g/m² to about 200 g/m². In another embodiment, the total thickness of the polymer material ranges from about 135 g/m² to about 155 g/m².

In one embodiment, the polymer material is selected from polyfunctional acrylates, polyfunctional methacrylates, polybutadienes, polyethylenes, polypropylenes, and mixtures thereof.

In one embodiment, the polymer material further comprises elastomeric materials.

In one embodiment, the elastomeric materials are selected from natural or synthetic rubber, or mixtures thereof.

In one embodiment, the polymer material is selected from ethylene propylene diene monomer (EPDM), polyethylene mixed with natural rubber, polyethylene mixed with synthetic rubber, polypropylene mixed with natural rubber, and polypropylene mixed with synthetic rubber. In another embodiment, the polymer material is a thermoplastic polyolefin roofing membrane (TPO).

In one embodiment, the polymer material comprises an average cross-linked density of about 30% to about 80%, about 35% to about 60%, or about greater than 40%. In one embodiment, the polymer material comprises and average cross-linked density of about greater than 40%.

In one embodiment, the present invention relates to a method of selectively cross-linking a polymer material using a particle beam processing device, comprising:

providing a particle beam generating assembly including at least one filament;

applying an operating voltage greater than or equal to about 150 kV to the filament to create a plurality of particles;

causing the plurality of particles to pass through a thin foil having a thickness of about 12.5 microns; and

treating a portion of the polymer material with the plurality of particles at a dosage of about 3 Mrads to about 12 Mrads, wherein the penetration depth of the plurality of particles is about 50% of the total thickness of the polymer material, and wherein said treatment results in the polymer material having an average cross-linked density of about 20% to about 100%, and wherein the polymer material has substantially the same properties as a polymer material having the same chemical composition and a higher cross-linked density.

In one embodiment, the present invention relates to a product made by any one of the processes described herein.

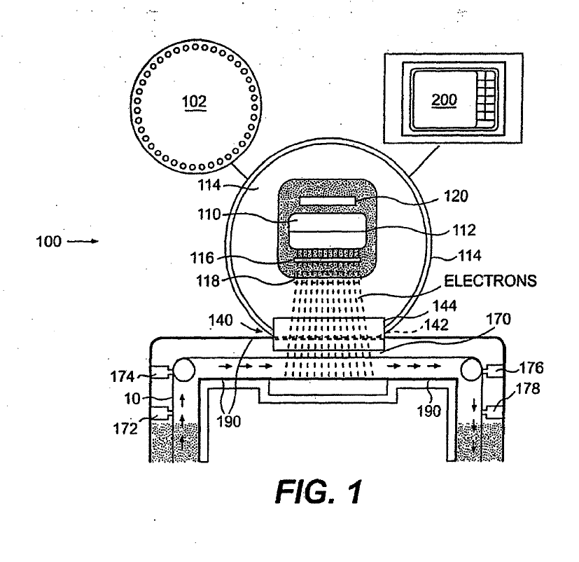

FIG. 1 schematically illustrates a particle beam processing device 100, including power supply 102, particle beam generating assembly 110, foil support assembly 140, and processing assembly 170. Power supply 102 provides an operating voltage of about 150 kVolts or more, such as in a range of about 150-300 kVolts, to the processing device 100. Power supply 102 may be of a commercially available type that includes multiple electrical transformers located in an electrically insulated steel chamber to provide high voltage to particle beam generating assembly 110 to produce particles, such as electrons.

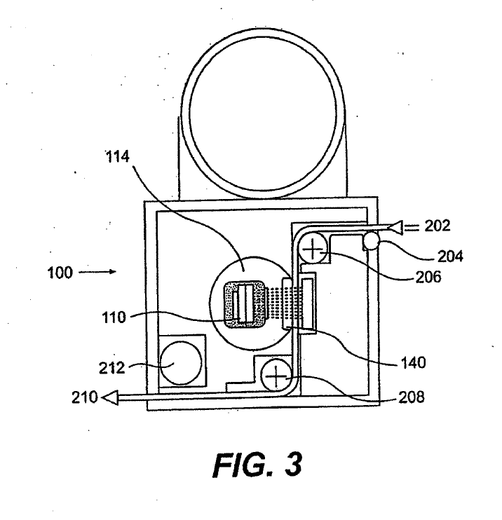

Particle beam generating assembly 110 is kept in a vacuum environment of vessel or chamber 114. In an EB processing device, particle generating assembly 110 is commonly referred to as an electron gun assembly. Evacuated chamber 114 may be constructed of a tightly sealed vessel in which particles, such as electrons, are generated. Vacuum pump 212 (shown in FIG. 3) is provided to create a vacuum environment in the order of approximately 10⁻⁶ Torr. Inside the vacuum environment of chamber 114, a cloud of electrons are generated around filament 112 when high-voltage power supply 102 sends electrical power to heat up filament 112.

Filament 112 then glows white hot and generates a cloud of electrons. Electrons are then drawn from filament 112 to areas of higher voltage, since electrons are negatively charged particles, as described below and accelerated to extremely high speeds. Filament 112 may be constructed of one or more wires commonly made of tungsten, and may be configured to be spaced evenly across the length of foil support 144 and emits electron beams across the width of a substrate 10.

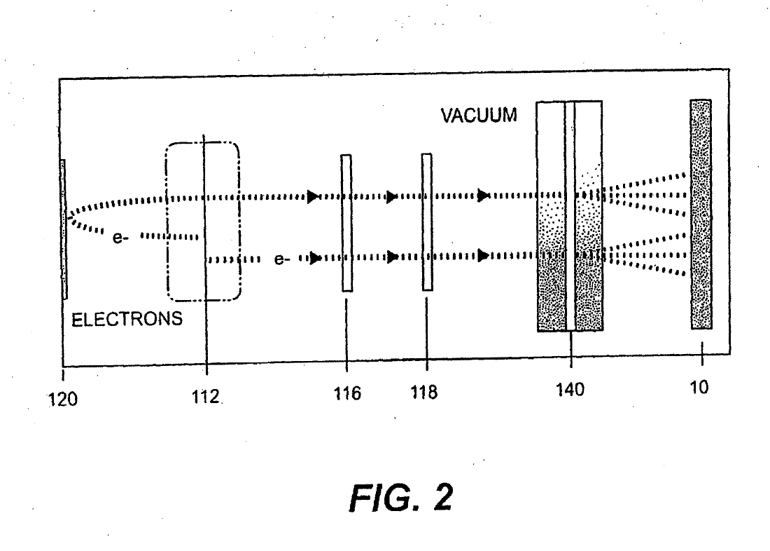

As shown in FIGS. 1 and 2, particle beam generating assembly 110 may include an extractor grid 116, a terminal grid 118, and a repeller plate 120. Repeller plate 120 repels electrons and sends the electrons toward extractor grid 116. Repeller plate 120 operates at a different voltage, preferably slightly lower, than filament 112 to collect electrons escaping from filament 112 away from electron beam direction as shown in FIG. 2.

Extractor grid 116, operating at a slightly different voltage, preferably higher than filament 112, attracts electrons away from filament 112 and guides them toward terminal grid 118. Extractor grid 116 controls the quantity of electrons being drawn from the cloud, which determines the intensity of the electron beam.

Terminal grid 118, operating generally at the same voltage as extractor grid 116, acts as the final gateway for electrons before they accelerate to extremely high speeds for passage through foil support assembly 140.

According to one embodiment of the present invention, for example, filament 112 may operate at −300,000 Volts and foil support assembly 140 may be grounded or set at 0 Volt. Repeller plate 120 may be selected to operate at −300,010 Volts to repel any electrons towards filament 112. Extractor grid 116 and terminal grid 118 may be selected to operate in a range of −300,000 Volts to −299,700 Volts.

The electrons then exit vacuum chamber 114 and enter the foil support assembly 140 through a thin foil 142 to penetrate a coated material or substrate 10 for the chemical reaction. The chemical reaction includes, for example, polymerization, cross-linking or sterilization. The speed of the electrons may be as high as or above 100,000 miles per second. Foil support assembly 140 may be made up of a series of parallel copper ribs (not shown). Thin foil 142, as shown in FIG. 1, is securely clamped to the outside of foil support assembly 144 to provide a leak-proof vacuum seal inside chamber 114. High speed electrons pass freely between the copper ribs, through thin foil 142 and into substrate 10 being treated. To prevent an undue energy loss, the foil is typically made as thin as possible while at the same time providing sufficient mechanical strength to withstand the pressure differential between the vacuum state inside particle generating assembly 110 and processing assembly 170.

The particle beam generating device can be made smaller in size and operate at a higher efficiency level when the thin foil of the foil support assembly is made of titanium or alloys thereof and having a thickness of about 12 micrometers or more. Alternatively, thin foil 142 may also be constructed of aluminum or alloys thereof having a thickness of 15 micrometers or more.

Once the electrons exit the foil support assembly 140, they enter the processing assembly 170 where the electrons penetrate a coating or web substrate 10 and cause a chemical reaction resulting in polymerization, crosslinking or sterilization. As shown in FIG. 3, the coating or web substrate 10 is being fed into the processing device 100 to enter processing assembly 170. Processing assembly 170 includes a web entrance 202 where substrate 10 enters, rollers 204, 206, and 208 to guide and deliver substrate 10 through the processing assembly 170, and a web exit 210 where substrate 10 exits the processing device 100. The product being treated is instantaneously transformed, needs no drying or cooling and contains many new and desirable physical properties. Products can be shipped immediately after processing.

The particle beam processing device may include a protective lining surrounding at least a portion of the periphery of the device to absorb radiation, such as X-ray, emitted when the electrons decelerate as they are absorbed in matter.

As shown in FIG. 1, a protective lining 190 surrounds the periphery of processing device 100, such as evacuated chamber 114 and processing assembly 170. Protective lining 190 absorbs substantially all X-rays created when electrons decelerate in matter. The thickness and material selected for protective lining 190 form a function primarily determined by the desired absorption rate of the X-rays. Protective lining 190 is capable of absorbing X-ray radiation at an absorption rate with residuals less than or equal to approximately 0.1 mrem/hour. The unit mrem/hour represents an absorption of 0.1 mili radiation equivalent to man per one hour. One milirem is equivalent to 1 milirad for electrons and X-rays. One way to measure the radiation emitted is by measuring the absorption at a distance of 10 cm away from protective lining 190 by an instrument such as an ionization chamber instrument commercially known as Bicron RSO-5. To further enhance safety measure of particle beam processing device 100, a safety interlock switches (not shown) may be provided to ensure safe operation by automatically stopping production whenever interlocks are opened.

The particle beam processing device may further include a processor, such as a computerized microprocessor, to regulate the quantity of electrons generated so the electron beam output is proportional to the feeding speed of the substrate. As shown in FIG. 1, a process control system 200 is provided to control several processes including but not limited to maintaining the required vacuum environment, initiating system operation with predetermined voltages and filament power, synchronizing electron generation with process speed to maintain constant treatment level, monitoring functions and interlocks, and providing warnings and/or alarms whenever the system functions exceed set limits or an interlock problem is detected.

In operation, particle beam processing device 100 works as follows. A vacuum pump 212 (shown in FIG. 3) evacuates air from chamber 114 to achieve a vacuum level of approximately 10⁻⁶ Torr, at which point processing device 100 is fully operational. In particle generating assembly 110, particle gun assembly components, including repeller plate 120, extractor grid 116, and terminal grid 118, are set at three independently controlled voltages which initiate the emission of electrons and guide their passage through foil support 144.

During the particle beam processing, a combination of electric fields inside evacuated chamber 114 create a “push/pull” effect that guides and accelerates the electrons toward thin foil 142 of foil support 144, which is at ground (0) potential. The quantity of electrons generated is directly related to the voltage of extractor grid 116. At slow production speeds, extractor grid 116 is set at a lower voltage than at high speeds, when greater voltage is applied. As the voltage of extractor grid 116 increases, so does the quantity of electrons being drawn from filament 112.

The coatings to be cured, for example, inks, adhesives and other coatings, generally require a low oxygen environment to cause the chemical conversion from a liquid state into a solid state. Therefore, the particle beam processing device may include, as illustrated in FIG. 1, a plurality of nozzles 172, 174, 176, and 178 distributed in processing zone 170 to inject gas other than oxygen to displace the oxygen therein. In one embodiment, nitrogen gas is selected to be pumped into processing zone 170 through nozzles 172, 174, 176, and 178 to displace the oxygen that would prevent complete curing.

Particle beam processing device 100 can be calibrated to achieve extremely high precision specification because process control system 200 may be set to provide the exact depth level of cure desired on a substrate or coating. Process control system 200 calculates the dose and the depth of electron penetration into the coating or substrate. The higher the voltage, the greater the electron speed and resultant penetration.

### EXAMPLE

The data taken in these experiments was measured utilizing thin film dosimetry techniques. Dosimetry techniques involve nylon films which have thicknesses in the range of 9-10 micrometers. The dosimeters contain a radiochromic dye that changes color from colorless to blue when the dye is exposed to electromagnetic radiation. The intensity of the blue color is directly proportional to the amount of radiation exposure obtained from the nylon films. By measuring the intensity or optical density of the blue color using a densitometer, one can convert the measured optical density to the absorbed dose in Mrads. The conversion from optical density to dose in Mrads is achieved by prior calibration of the dosimeters and the densitometer using Co⁶° Gamma facility at the National Institute of Standards and Technology, Gaithersburg, Md. These experiments utilized Dosimeters Model FWT-60-810 manufactured by Far West Technology, Goleta, Calif. and Densitometer Model 92 SXN 3285 manufactured by Far West Technology, Goleta, Calif.

### Example 1

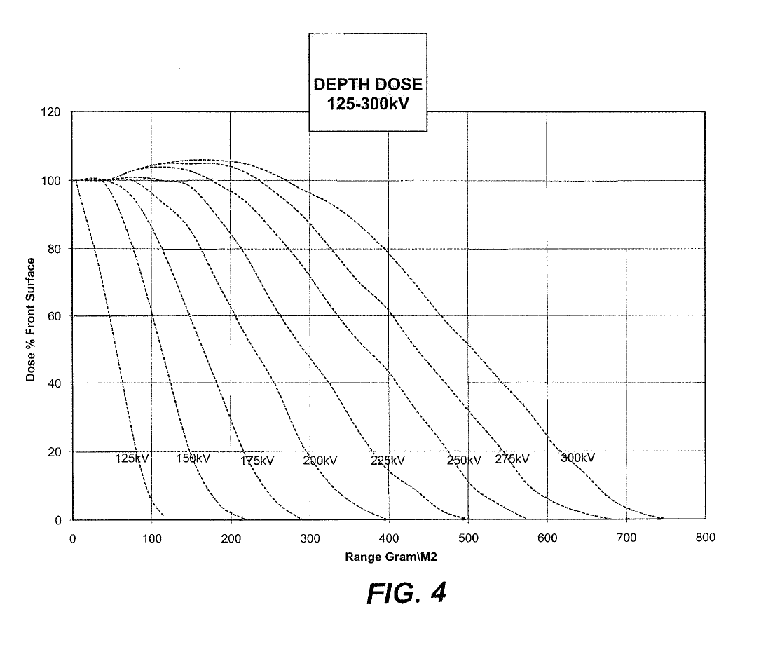

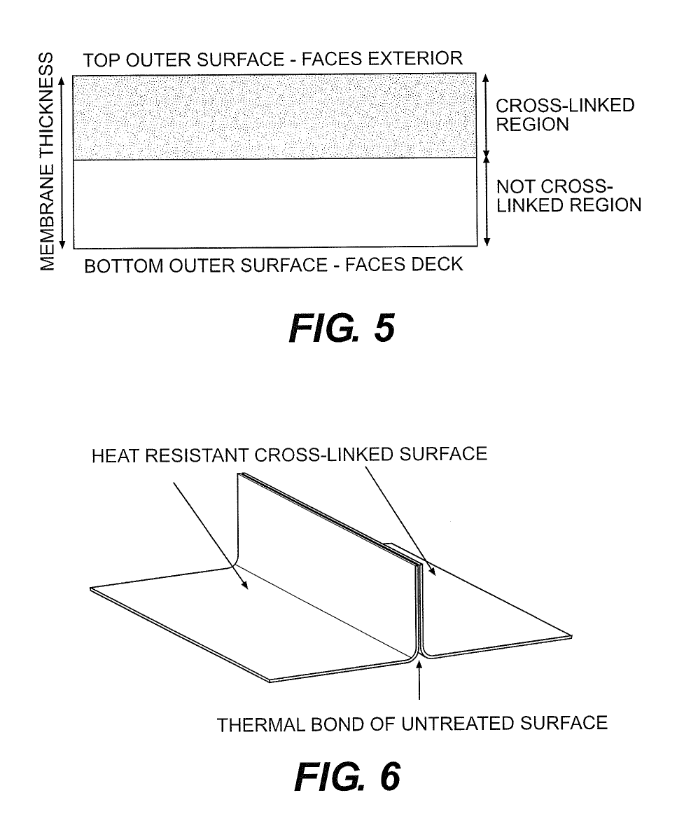

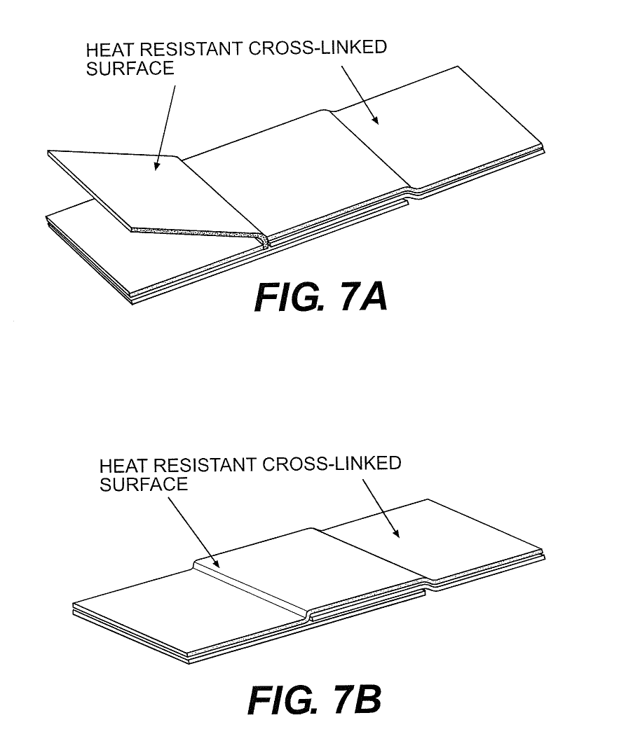

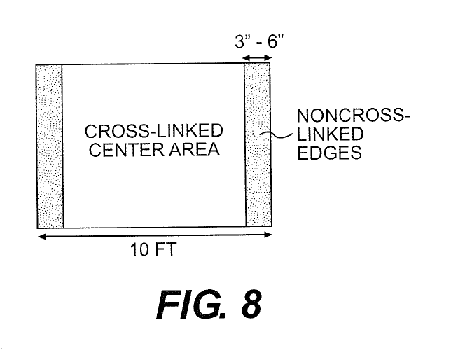

As shown in FIG. 4, the particle beam processing device 100 using thin foil 142 that is made of titanium having a thickness of about 12 micrometers improves the electron penetration in substrate 10.

Thin film nylon dosimeters were used to measure the penetration capability of electrons. A thin titanium foil of 12.5 microns was used. An EPDM roofing membrane having a thickness of 0.050 inches and a density of 1.26 gram/M² was treated independently across the entire length of both sides of the membrane with the particle beam processing device at a rate of 50 feet/minute with 300 kVolts and a dosage of 10.0 Mrads.

The resulting membrane contained an average cross-linked density of about >40%. No detrimental effects to the membrane were observed. Because the membrane was dosed at 10 Mrads, both sides of the membrane had dose penetration to 700 gram/m², leaving about 200 grams/m² untreated (i.e., uncross-linked). Surprisingly, even though the center portion of the membrane remained uncross-linked, the resulting membrane was adequate for commercial use, and had substantially similar properties when compared to the same material treated at higher dosing, or the same material having a higher average cross-linked density.

If one were to increase the dosage for example to 12.5 Mrads or 15 Mrads, and maintain the same parameters set forth above, it would be expected that the penetration depth of the particles would be the same for an EPDM roofing membrane having a thickness of 0.050 inches and a density of 1.26 gram/M². Also, due to the increased number of particles one would expect to achieve a higher average cross-linked density material. However, it has been unexpectedly shown above that higher average cross-linked densities are not always necessary to produce a membrane with beneficial properties.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims and their equivalents.

What is claimed is:

1. A method of selectively cross-linking a polymer material using a particle beam device, comprising,
selectively treating a portion of the polymer material with a particle beam for a sufficient period of time to produce a cross-linked portion, wherein
said treatment results in the polymer material having an average cross-linked density of about 20% to about 100%, and
wherein the polymer material has substantially the same properties as a polymer material having the same chemical composition and a higher cross-linked density.

2. The method of claim 1, wherein the particle beam assembly comprises at least one filament.

3. The method of claim 2, wherein an operating voltage greater than or equal to about 150 KV is applied to the filament to create a plurality of particles.

4. The method of claim 3, wherein the plurality of particles pass through a thin foil having a thickness of about 12.5 microns.

5. The method of any one of claims 1-4, wherein the polymer material is treated at a dosage of about 3 Mrads to about 12 Mrads.

6. The method of any one of claims 1-5, wherein the plurality of particles penetrates said portion of the polymer material at a depth of about 50% of the total thickness.

7. The method of any one of claims 1-6, wherein said portion comprises a single surface of the polymer material.

8. The method of any one of claims 1-7, wherein said portion comprises two single surfaces of the polymer material.

9. The method of any one of claims 1-8, wherein said portion of the polymer material comprises a center portion of the single surface.

10. The method of any one of claims 1-9, wherein the edges of the polymer material are left untreated.

11. The method of claim 2, wherein said operating voltage ranges from about 150 kV to about 300 kV.

12. The method of claim 4, wherein the thin foil is a titanium foil.

13. The method of any one of claims 1-12, wherein the total thickness of the polymer material ranges from about 100 g/m² to about 200 g/m².

14. The method of any one of claims 1-13, wherein the total thickness of the polymer material ranges from about 135 g/m² to about 155 g/m².

15. The method of any one of claims 1-14, wherein the polymer material is selected from polyfunctional acrylates, polyfunctional methacrylates, polybutadienes, polyethylenes, polypropylenes, and mixtures thereof.

16. The method of any one of claims 1-15, wherein the polymer material further comprises elastomeric materials.

17. The method of claim 16, wherein the elastomeric materials are selected from natural or synthetic rubber, or mixtures thereof.

18. The method of any one of claims 1-15, wherein the polymer material is selected from ethylene propylene diene monomer (EPDM), polyethylene mixed with natural rubber, polyethylene mixed with synthetic rubber, polypropylene mixed with natural rubber, and polypropylene mixed with synthetic rubber.

19. The method of any one of claims 1-18, wherein the polymer material is a thermoplastic polyolefin roofing membrane.

20. The method of any one of claim 1-19, wherein the average cross-linked density of the polymer material is about 30% to about 80%.

21. The method of any one of claims 1-20, wherein the average cross-linked density of the polymer material is about greater than 40%.

22. A product made by any one of the proceeding claims.
